(19) United States
(12) Patent Application Publication
(10) Pub. No.: US 2002/0075057 A1
(43) Pub. Date: Jun. 20, 2002

(54) Superconducting power circuit

(75) Inventors: Shoji Tanaka, Tokyo (JP); Naoki Koshizuka, Tokyo (JP); Keiichi Tanabe, Tokyo (JP); Youichi Enomoto, Tokyo (JP)

Correspondence Address: OSTROLENK FABER GERB & SOFFEN, 1180 AVENUE OF THE AMERICAS, NEW YORK, NY, 100368403

(73) Assignee: International Superconductivity Technology Center, The Juridical Foundation

(21) Appl. No.: 10/007,199

(22) Filed: Oct. 19, 2001

(30) Foreign Application Priority Data
Oct. 26, 2000 (JP) 2000-327423

(51) Int. Cl. H03K 17/92

(52) U.S. Cl. 327/367

(57) ABSTRACT

A superconducting power circuit comprises a bridge circuit, comprising superconducting switch elements having two or more Josephson junctions incorporated at each side of a rhombus-shaped bridge line, the superconducting switch elements being freely switchable by an outside magnetic field; and a control section which uses the outside magnetic field to switch one pair of the superconducting switch elements, arranged on opposite sides of the bridge circuit, to a superconductive state, and switch another pair of the superconducting switch elements to a normal-conductive state; the superconducting power circuit enables a large low-voltage dc current to be converted with high efficiency.

### BACKGROUND OF THE INVENTION

1. Field of the Invention

The present invention relates to a superconducting power circuit, and more particularly to a superconducting power circuit for ac/dc conversion which can convert ac current to dc current, and vice versa.

2. Description of the Related Art

In a superconducting power circuit comprising a Josephson junction device, when operating a single flux quantum (SFQ) circuit, the Josephson junction must be switched to the voltage state and magnetic flux quantum must be led into a SQUID (superconducting quantum interference device). To stably lead a magnetic flux into the SQUID, a dc bias current must be applied to the Josephson junction at all times. Since a bias current of approximately 80% of the critical current of the Josephson junction device is usually applied per Josephson junction device, the amount of bias current applied to the entire circuit is calculated by multiplying the amount of the bias current applied per Josephson junction device by the number of Josephson junction devices.

For example, when the critical current is 0.2 mA, which is the standard in present Josephson junction devices, a dc current of approximately 16 A is needed to drive a circuit having a number of junctions of approximately 10⁵.

On the other hand, the SFQ circuit is at the voltage state only while a short pulse is passing therethrough, and has zero superconductivity at all other times. Therefore, the voltage in the SFQ circuit is extremely low. As a consequence, the SFQ circuit requires a large, low-voltage dc current. Furthermore, an even larger current is required when a device comprising a great number of SFQ circuits is provided in a system.

In attempting to supply this kind of large, low-voltage dc current from outside the circuit, or outside the apparatus to the SFQ circuit, since the resistance is finite even if a low-resistance line is used, heat proportionate to the square of the current is generated, causing loss.

Conventionally, a power circuit for ac/dc conversion using a semiconductor element, a chemical battery, or the like, is used as the dc power supply. However, these conventional dc power supplies can only supply a voltage of approximately several V, and cannot easily achieve a large dc current at a low voltage on the order of μV to mV.

In particular, a power circuit decreasing ac current by a transformer and ac/dc converting using a rectifying element such as a diode, or a semiconductor element such as a thyristor, is used as a power supply for the large current. However, since the large current generates a great amount of heat, efficiency decreases; and since the resistance of the circuit itself is considerable, it is difficult to be a low voltage.

### BRIEF SUMMARY OF THE INVENTION

To solve the problems described above, an object of the present invention is to provide a superconducting power circuit which can obtain a large low-voltage dc current with high conversion efficiency.

In order to achieve the above object, the present invention has the following constitution.

A superconducting power circuit comprises a bridge circuit comprising superconducting switch elements having two or more Josephson junctions incorporated at each side of a bridge line; and a control section which uses an outside magnetic field to switch a pair of the superconducting switch elements, arranged on opposite sides of the bridge circuit, to a superconductive state for maintaining a supercurrent, and switch another pair of the superconducting switch elements to a normal-conductive state suppressing a supercurrent.

According to this aspect of the superconducting power circuit, the bridge circuit is comprised of superconducting switch elements which can be freely switched between superconductive and normal-conductive states by an outside magnetic field. Therefore, an ac current can be converted to dc current, and vice versa. Moreover, since the electrical resistance of the superconducting switch elements becomes zero, a large low-voltage ac or dc current can be input thereto, making the circuit suitable for supplying power to an SFQ circuit.

In another aspect of the superconducting power circuit, when the voltage of an ac current applied to the bridge circuit is positive, the control section switches the pair of the superconducting switch elements to the superconductive state, and switches the other pair of the superconducting switch elements to the normal-conductive state. On the other hand, when the voltage of an ac current applied to the bridge circuit is negative, the control section switches the pair of the superconducting switch elements to the normal-conductive state, and switches the other pair of the superconducting switch elements to the superconductive state.

According to this aspect, since the control section switches the superconducting switch elements in accordance with the voltage polarity of the input ac current, the ac current can be all-wave rectified, and, since the switching speed of the Josephson junctions provided in the superconducting switch elements is rapid, a high-frequency ac current can be easily rectified.

In another aspect of the above superconducting power circuit, the control section comprising a polarity detecting section which detects the polarity of the ac current, a control signal power supply which generates a control current based on the detection result of the polarity detecting section, and a magnetic field generating section, which is provided adjacent to the superconducting switch elements and switches the superconducting switch elements by converting the control current to the outside magnetic field.

According to this aspect of the superconducting power circuit, since the control section comprises the polarity detecting section, the control signal power supply, and the magnetic field generating section, the superconducting switch elements can be switched by using a simple circuit constitution.

In another aspect of the above superconducting power circuit, a transformer comprises at least a secondary winding composed of a superconducting line, and is connected to the input side of the bridge circuit.

In another aspect of the above superconducting power circuit, a dc power supply is connected to the input side of the bridge circuit.

In another aspect of the superconducting power circuit, the superconducting switch elements comprising two or more Josephson junction elements or two or more superconducting quantum interference devices, comprising two Josephson junctions, connected in parallel.

According to this aspect of the superconducting power circuit, since the superconducting switch elements comprising two or more Josephson junction elements or superconducting quantum interference devices, connected in parallel, the integral of the critical current of the Josephson junction and the number of junctions becomes the critical current of the superconducting switch elements, increasing the amount of current flowing in the superconducting switch elements.

In another aspect of the superconducting power circuit of the present invention, the Josephson junction comprises a bicrystal superconducting film which is grown by liquid phase epitaxy on a bicrystal substrate, comprising at least two or more crystal phases which are joined at a junction interface.

According to this aspect of the superconducting power circuit, since the Josephson junction comprises a bicrystal superconducting film which is grown by liquid phase epitaxy, the bicrystal superconducting film can be made thicker, increasing the amount of the critical current of the Josephson junction and enabling an even larger current to be supplied.

In another aspect of the superconducting power circuit of the present invention, when a symmetrical bicrystal substrate is one in which the angles between axes of adjacent crystal phases and the junction interface are symmetrical with the crystal grain interface as a reference, the four superconducting switch elements comprise Josephson junctions which are comprised of bicrystal superconducting film provided on the symmetrical substrate.

According to this aspect of the superconducting power circuit, the Josephson junctions are comprised of bicrystal superconducting film provided on the symmetrical substrate, and have maximum critical current when the magnetic field is zero. Therefore, the superconducting switch element can be made superconductive by applying an outside magnetic field of zero, making the switch element suitable for use in the superconducting power circuit.

In another aspect of the superconducting power circuit of the present invention, when an asymmetrical bicrystal substrate is one in which the angles between axes of adjacent crystal phases and the junction interface are asymmetrical with the crystal grain boundary as a reference, the four superconducting switch elements comprise Josephson junctions which are comprised of bicrystal superconducting film provided on the asymmetrical substrate.

According to this aspect of the superconducting power circuit, the Josephson junctions are comprised of bicrystal superconducting film provided on the asymmetrical substrate, and have zero critical current when the magnetic field is zero. Therefore, the superconducting switch element can be switched to the normal-conductive state by applying an outside magnetic field of zero, making the switch element suitable for use in the superconducting power circuit.

In another aspect of the superconducting power circuit of the present invention, when a symmetrical bicrystal substrate is one in which the angles between axes of adjacent crystal phases and the junction interface are symmetrical with the crystal grain interface as a reference, and an asymmetrical bicrystal substrate is one in which the angles between axes of adjacent crystal phases and the junction interface are asymmetrical with the crystal grain interface as a reference, the pair of superconducting switch elements comprise Josephson junctions which are comprised of bicrystal superconducting film provided on the symmetrical substrate, and the other pair of superconducting switch elements comprise Josephson junctions which are comprised of bicrystal superconducting film provided on the asymmetrical substrate.

According to this aspect of the superconducting power circuit, the circuit comprises superconducting switch elements which become superconductive state when the outside magnetic field is zero, and superconducting switch elements become normal-conductive state when the outside magnetic field is zero. Therefore, the ac current can be all-wave rectified merely by switching the magnetic field on and off, thereby simplifying the constitution of the control section.

According to the superconducting power circuit of the present invention, superconducting switch elements, which can be freely switched between normal-conductive and superconductive states, are incorporated in a bridge. Therefore, ac current can be converted to dc current, and vice versa. Furthermore, since the electrical resistance of the superconducting switch elements becomes zero, a high ac or dc current of low-voltage can be input thereto, the superconducting power circuit can be suitably used as a power supply of the circuit of superconductors.

Consequently, a large-scale superconducting integrated circuit system using a single flux quantum can be high-efficiently operated, reducing energy consumption.

In addition to a power supply for a superconducting integrated circuit, the superconducting power circuit of the present invention can also be applied as a power supply for exciting a superconducting magnet.

### BRIEF DESCRIPTION OF THE SEVERAL VIEWS OF THE DRAWINGS

FIG. 1 is a circuit diagram showing a superconducting power circuit according to a first embodiment of the present invention.

FIG. 2 is a graph showing field dependency of a critical current of a symmetrical Josephson junction of a superconductive switch element.

FIG. 3 is a graph showing the relationship between the voltages of an input ac current, control currents, and time.

FIG. 4 is a diagram showing a plan view of one example of a superconductive switch element which is used in the superconducting power circuit of FIG. 1.

FIG. 5 is a cross-sectional view taken along the line X-X′ in FIG. 4.

FIG. 6 is an enlarged perspective view of a Josephson junction comprising a primary part of the superconductive switch element of FIG. 4.

FIG. 7 is a plan view of another example of a superconductive switch element which is used in the superconducting power circuit of FIG. 1.

FIG. 8 is a cross-sectional view taken along the line Y-Y′ in FIG. 7.

FIG. 9 is a side view of the superconductive switch element shown in FIG. 7.

FIG. 10 is a schematic view of a liquid phase growth apparatus used in manufacturing a superconductive switch element.

FIG. 11A shows one example of a process in a manufacturing method of a bicrystal substrate, being a perspective view of the pasting of six single-crystal substrates.

FIG. 11B is a perspective view of the body formed by sintering the single-crystal substrates of FIG. 11A.

FIG. 11C is a perspective view of a bicrystal substrate which is formed by cutting along the dashed line of FIG. 11B, and polishing and smoothing the cut face.

FIG. 12 is a circuit diagram showing a superconducting power circuit according to a second embodiment of the present invention.

FIG. 13 is a graph showing field dependency of a critical current of a symmetrical Josephson junction and an asymmetrical Josephson junction of a superconductive switch element.

FIG. 14 is a graph showing the relationship between the voltages of an input ac current, control currents, and time.

FIG. 15 is an enlarged perspective view of an asymmetrical Josephson junction.

### DETAILED DESCRIPTION OF THE INVENTION

Embodiment 1

A first embodiment of the present invention will be explained with reference to the drawings.

A superconducting power circuit A according to the first embodiment of the present invention converts ac current to dc current, and mainly comprises a bridge circuit 5, comprised by arranging four superconducting switch elements 1, 2, 3, and 4, on each side of a rhombus-shaped bridge line, and a controller 6 which switches the superconducting switch elements 1 to 4.

The bridge circuit 5 is usually a rhombus, but is not limited to this shape when actually provided on a circuit board, and may be round, square, or rectangular.

A transformer 8 is connected via input lines 7 to terminals 5a and 5b on the input side of the bridge circuit 5. The input lines 7 are connected to a secondary coil 9 of the transformer 8, and an ac power supply 11 is connected to a primary coil 10 of the transformer 8.

The transformer 8 converts high-voltage and low-current ac current, input from the ac power supply 11, to low-voltage and high-current input ac current Iᵢₙ.

Furthermore, a capacitor 13 is connected in series via output lines 12 to terminals 5c and 5d on the output side of the bridge circuit 5, and an outside circuit 14 is connected in parallel with the capacitor 13. An inductance 15 is connected in series to the outside circuit 14. The capacitor 13 and the inductance 15 form a low pass filter.

In the superconducting power circuit A of the present invention, the secondary coil 9 of the transformer 8, the input lines 7, the output lines 12, the capacitor 13, the inductance 15, and the outside circuit 14 comprise superconductors.

In the bridge circuit 5, one pair of the superconducting switch elements 1 and 3 are provided opposite each other, and the other pair of superconducting switch elements 2 and 4 are provided opposite each other at another position.

The superconducting switch elements 1 to 4 have two or more Josephson junctions which can be freely switched to/from normal conductivity and superconductivity by an outside magnetic field. Each Josephson junction comprises what is termed an s-s wave junction, and, as shown in FIG. 2, the magnetic field dependency of the critical current of the elements comprising the Josephson junction is characterized in that the critical current I_{c} reaches its maximum when the magnetic field H is zero, and becomes zero when the magnetic field H is ±H₁.

That is, the superconducting switch elements 1 to 4 become superconductive when the outside magnetic field is zero, and become normal-conductive when the outside magnetic field is applied thereto.

The critical current of one Josephson junction is very small, being approximately 0.2 mA, but since the superconducting switch elements 1 to 4 of the present invention comprise two or more Josephson junctions, the critical current of the superconducting switch elements 1 to 4 themselves can be increased by the number of the Josephson junctions, making it possible to feed a high current therethrough.

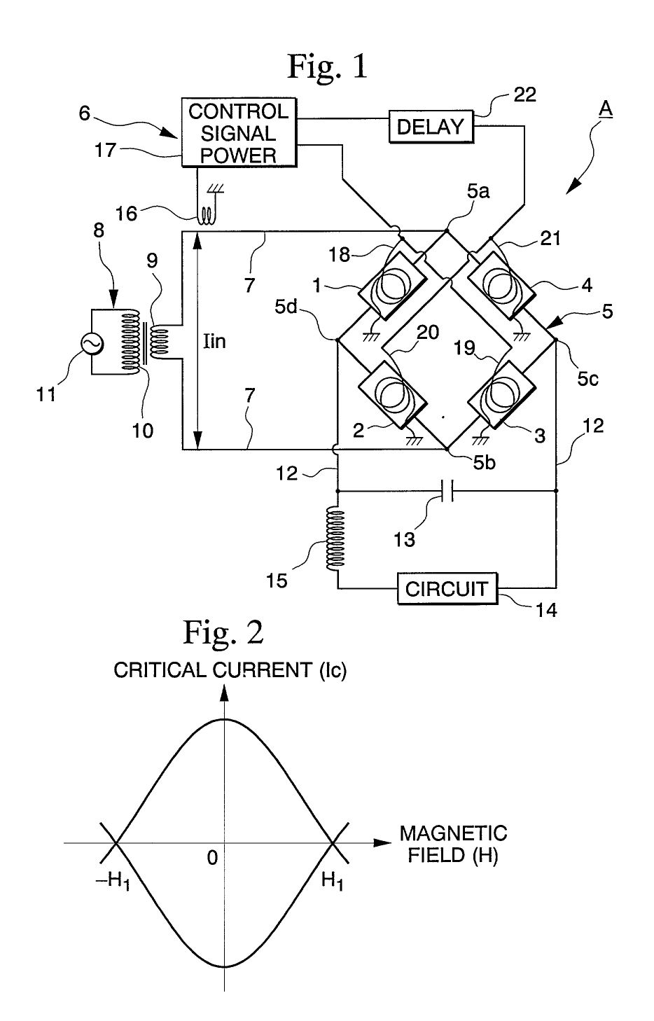

As shown in FIG. 1, the controller 6 comprises a polarity detector 16, comprising a coil and the like provided adjacent to the input lines 7, a control signal source 17 which generates a rectangular control current based on the result detected by the polarity detector 16, and coils 18 to 21 which function as a magnetic field generating section, provided adjacent to the superconducting switch elements 1 to 4. The coils 18 and 19 split from the control signal source 17 and are provided near the superconducting switches 1 and 3 respectively, and the coils 20 and 21 split from the control signal source 17 and are provided near the superconducting switches 2 and 4 respectively.

A delay circuit 22 is inserted between the control signal source 17 and the coils 20 and 21.

In the polarity detector 16, the input ac current Iᵢₙ induces a detected current, which is input to the control signal source 17. The control signal source 17 amplifies the detected current, and supplies a rectangular-wave control current to the coils 18 to 21.

The size of the magnetic field generated by the coils 18 to 21 depends on the capability of the superconducting switch elements 1 to 4; in the present invention, a magnetic field of approximately 3×10⁻⁴ T (tesla) is required. The magnetic field generating section is not limited to the coils 18 to 21 in this invention, and it is acceptable to provide control current lines as a magnetic field generating section near the superconducting switch elements 1 to 4, and to switch the superconducting switch elements 1 to 4 by using the magnetic field from the current lines.

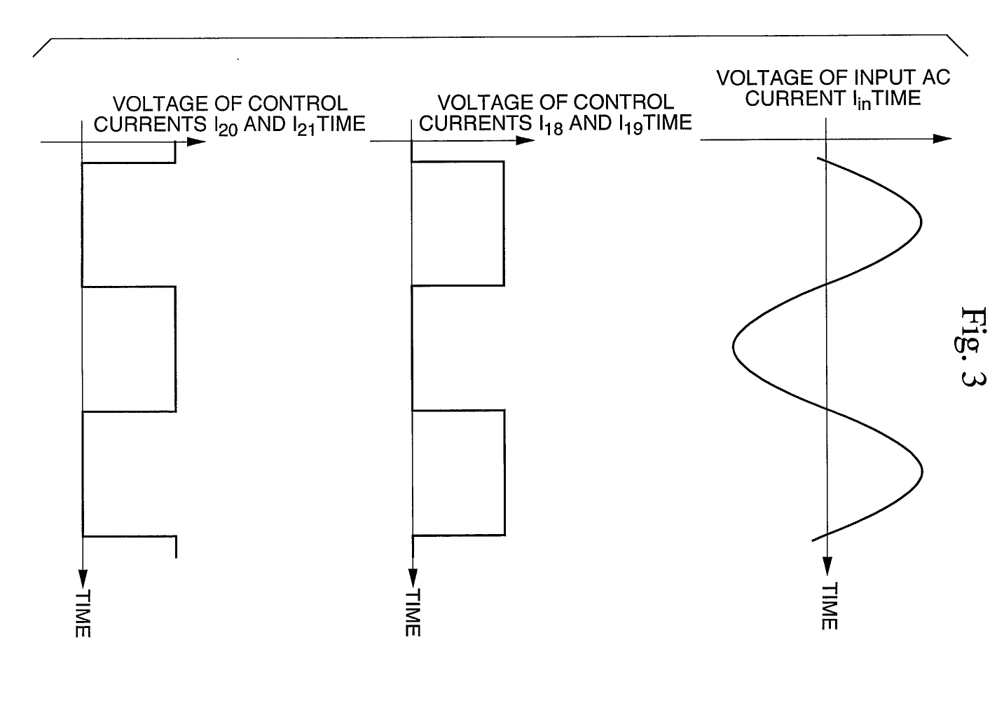

FIG. 3 shows wave forms of the input ac current Iᵢₙ, which is input to the bridge circuit 5, the control currents 1₁₈ and I₁₉, which are applied to the coils 18 and 19, and the control currents I₂₀ and I₂₁, which are applied to the coils 20 and 21.

As shown in FIG. 3, since the rectangular wave control current of the control signal source 17 has the same phase as the input ac current Iᵢₙ, the control currents I₁₈ and I₁₉, which are applied to the coils 18 and 19, have the same phase as the input ac current Iᵢₙ. On the other hand, since the delay circuit 22 delays the phase of the control current, the phases of the control currents I₂₀ and I₂₁, which are applied to the coils 20 and 21, are delayed by one-half cycle with respect to the input ac current Iᵢₙ.

Subsequently, the operation of the superconducting power circuit A will be explained.

When the outside magnetic field is applied to the superconducting switch elements 1 to 4, the superconducting switch elements 1 to 4 switch from the superconductive state to the normal-conductive state; consequently, when the voltage of the input ac current Iᵢₙ is positive, the control currents I₁₈ and I₁₉ apply an outside magnetic field to the pair of superconducting switch elements 1 and 3, making the superconducting switch elements 1 and 3 normal-conductive.

When the voltage of the input ac current Iᵢₙ, is positive, the control currents 120 and 121, are zero; consequently, the outside magnetic field is not applied to the superconducting switch elements 2 and 4, which remain superconductive.

The superconducting switch elements 2 and 4 have zero electrical resistance in the superconductive state, and therefore become nonresistant; the superconducting switch elements 1 and 3 have a finite value of the electrical resistance in the normal-conductive state, and therefore their electrical resistances become finite resistances. Consequently, current in the superconducting power circuit A flows through the superconducting switch elements 2 and 4 but not through the superconducting switch elements 1 and 3.

Therefore, when the voltage of the input ac current Iᵢₙ is positive, the current in the superconducting power circuit A flows from the terminal 5a via the superconducting switch element 4 to the terminal 5c, via the outside circuit 14, and then from the terminal 5d via the superconducting switch element 2 to the terminal 5b.

As time elapses and the voltage of the input ac current Iᵢₙ has become negative, in converse to the case described above, the superconducting switch elements 2 and 4 switch from the superconductive state to the conductive state and their resistances become finite resistances, whereas the superconducting switch elements 1 and 3 switch from the conductive state to the superconductive state and their resistances become zero.

As a result, the current in the superconducting power circuit A flows through the superconducting switch elements 1 and 3 but not through the superconducting switch elements 2 and 4; therefore, the current in the input ac current Iᵢₙ in this case flows from the terminal 5b via the superconducting switch element 3 to the terminal 5c, via the outside circuit 14, and then from the terminal 5d via the superconducting switch element 1 to the terminal 5a.

As a result, even when the polarity of the input ac current Iᵢₙ has changed, current on the output side of the bridge circuit 5 always flows from the terminal 5c via the outside circuit 14 to the terminal 5d. That is, dc current flows to the outside circuit 14.

By using the controller 6 to switch one pair of the superconducting switch elements to the superconductive state, and switch the other pair to the normal-conductive state in this way, ac current can be converted to dc current.

Subsequently, the constitution of the superconducting switch elements 1 to 4 will be explained in greater detail.

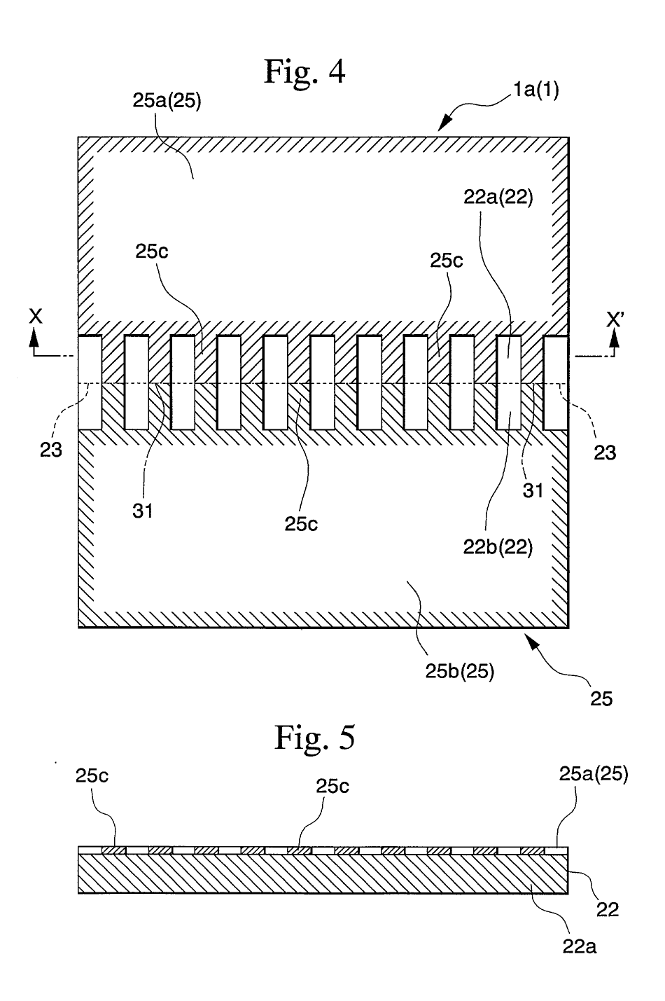

FIGS. 4 to 6 show one example of the detailed constitution of the superconducting switch element 1 of the present invention. The superconducting switch elements 2 to 4 have exactly the same constitution as the superconducting switch element 1.

As shown in FIGS. 4 and 5, the superconducting switch element 1a (1) comprises two or more Josephson junctions 31, connected in parallel and arranged on a straight line.

The superconducting switch element 1a comprises a bicrystal substrate (bicrystal base) 22, and an oxide superconducting film 25, provided on the bicrystal substrate 22 by using a liquid phase epitaxial method.

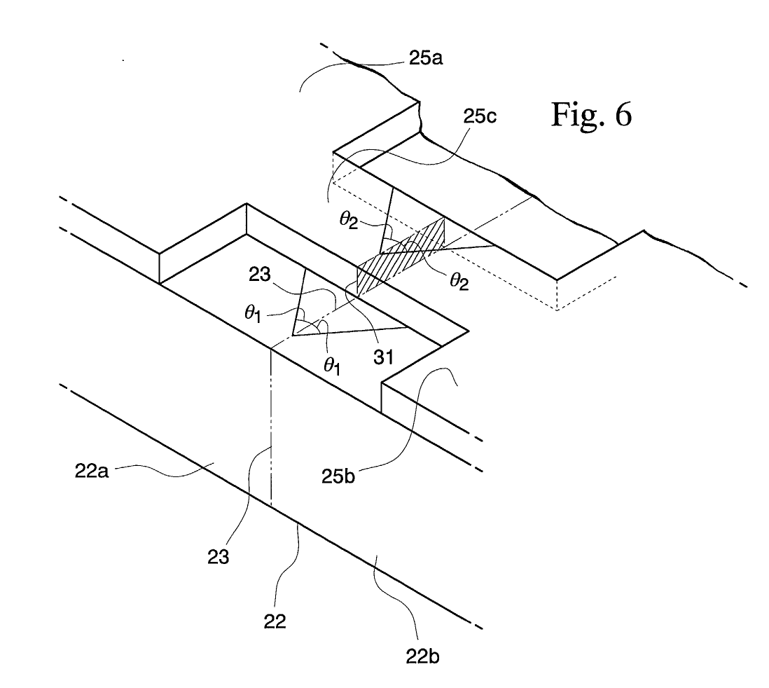

As shown in FIG. 6, the bicrystal substrate 22 comprises two crystal phases 22a and 22b, which are coupled together with a junction interface 23 therebetween. The two crystal phases 22a and 22b are comprised of the same material, for example, magnesium oxide (MgO), titanic oxide strontium (SrTiO₃), gallium oxide neodymium (NdGaO₃), or the like; MgO is particularly preferable.

In the bicrystal substrate 22, the two crystal phases 22a and 22b are coupled at the same angle, so that the angles θ₁ between the axes of the (100) faces of the crystals and the junction interface 23 are the same. For example, the angle θ₁ may be 22.5 degrees. The axes of the (100) faces of the two crystal phases 22a and 22b are thus symmetrical with the junction interface 23 as a reference. In the present invention, this type of bicrystal substrate 22 will be termed a “symmetrical base”.

The oxide superconducting film 25 is provided on approximately the entire faces of the bicrystal substrate 22, and is provided in the teeth of a comb-like shape near the junction interface 23 of the bicrystal substrate 22.

As shown in FIGS. 4 to 6, the oxide superconducting film 25 comprises terminal films 25a and 25b, provided on the crystal phases 22a and 22b, and a great number of junction film sections 25c, which join the terminal films 25a and 25b with crossing the junction interface 23.

Since the oxide superconducting film 25 is grown by liquid phase epitaxy, its crystal structure reflects that of the crystal phases 22a and 22b of a substrate. That is, the crystal axis direction of the oxide superconducting film 25 is different on either side of the junction interface 23 of the bicrystal substrate 22, the crystal axis direction of the terminal film 25a and the junction film section 25c of the terminal film 25a reflecting the crystal structure of the crystal phase 22a, and the crystal axis direction of the terminal film 25b and the junction film section 25c of the terminal film 25b reflecting the crystal structure of the crystal phase 22b.

Therefore, the crystal axes of the junction film sections 25c are in different directions on either side of the junction interface 23 and the angle θ₂ between the junction interface 23 and the crystal axis of the junction film sections 25c on the terminal film 25a side of the junction interface 23 is symmetrical with the angle θ₂ between the junction interface 23 and the crystal axis of the junction film sections 25c on the terminal film 25b side of the junction interface 23, with the junction interface 23 as a reference.

Consequently, Josephson junctions 31 are obtained at the junction film sections 25c on the junction interface 23.

In FIG. 4, the Josephson junctions 31 are represented by the dashed line, and, in FIG. 6, the Josephson junction 31 is represented by a diagonally shaded section. In the present invention, the Josephson junction 31, formed on the junction interface 23 of a symmetrical base as described above, will be termed a “symmetrical Josephson junction”.

The magnetic field dependency of the critical current of the symmetrical Josephson junction 31 is the same as that shown in FIG. 2, the critical current I_{c} reaching its maximum when the magnetic field H is zero, and the critical current I_{c} becoming zero when the magnetic field H is ±H₁. Therefore, the magnetic field from the coil 18 can be used to switch the superconducting switch element 1 from the superconductive state to the normal-conductive state, and vice versa. The magnetic field responsivity of the switching is extremely rapid, having a switching speed of several picoseconds per switch. Therefore, even when high-frequency current is input to the bridge circuit 5, trouble caused by delays in the switching speed can be prevented.

The width and thickness of the Josephson junction 31 match the width and film-thickness of the junction film sections 21c. Preferably, the width and thickness should be slightly larger than the magnetic field penetration depth of the Josephson junction 31. For instance, when the magnetic field penetration depth is 2 μm, the width and thickness of each of the junction film sections 21c should be approximately 5 μm.

In FIG. 4, only ten Josephson junctions 31 (unction film sections 25c) are shown in the superconducting switch element 1a, but in reality, several thousand to several ten-thousand Josephson junctions 31 are provided.

Since the superconducting switch element 1a comprises multiple Josephson junctions 31 connected in parallel, the critical current of the entire element 1 is the integral of the critical current of a Josephson junction 31 and the number of Josephson junctions 31 per single element. Therefore, in order to increase the large current to the superconducting switch element 1, the number of Josephson junctions per element need only be increased.

The critical current of the Josephson junction 31 depends on the size of the junction area, and is usually between several zero-point mA to several mA. For example, when the critical current of the Josephson junction 31 is 0.3 mA, and ten-thousand Josephson junctions 31 are provided for each element, the total critical current of the super-conducting switch element 1a becomes 3A.

In order to increase the number of Josephson junctions 31 which are provided per superconducting switch element 1a, a Josephson junction may be formed in each oxide superconducting film by using a multilayered structure, obtained by laminating multiple oxide superconducting films 25 on the substrate 22.

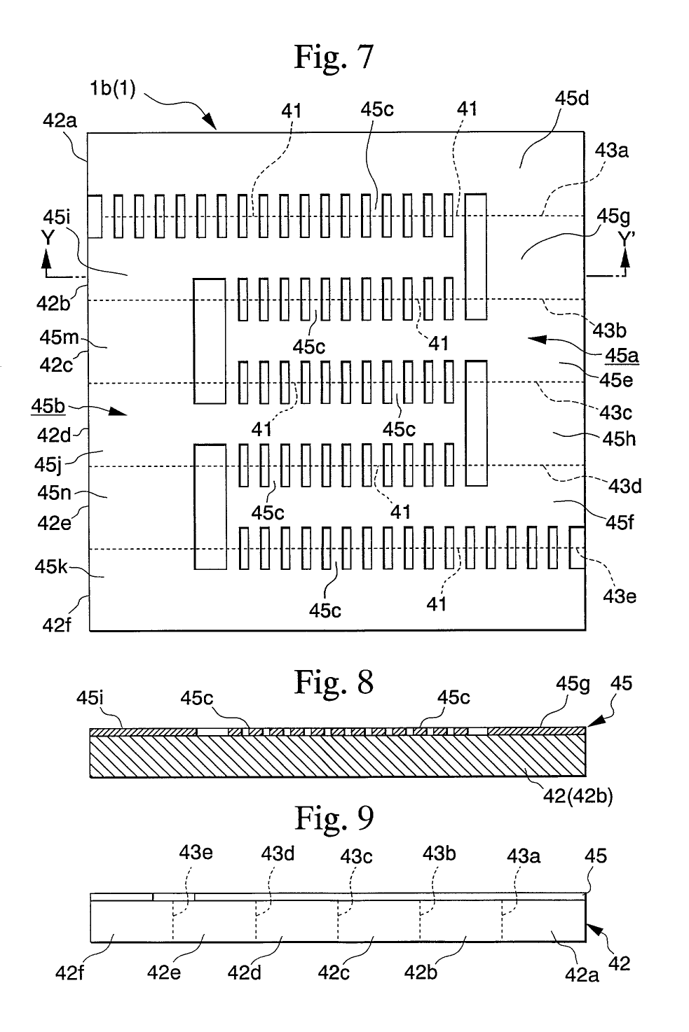

Subsequently, another example of the superconducting switch element 1 will be explained with reference to FIGS. 7 and 8.

FIGS. 7 and 8 show another example, being the detailed constitution of the superconducting switch element 1b (1) of the present invention. The constitution of the other superconducting switch elements 2 to 4 is identical to that of the superconducting switch element 1 shown in FIGS. 7 and 8.

As shown in FIGS. 7 and 8, the superconducting switch element 1b comprises two ore more Josephson junctions 41, which are connected in parallel and in multiple rows.

That is, the superconducting switch element 1b comprises a bicrystal substrate (bicrystal base) 42, and an oxide superconducting film 45, grown on the bicrystal substrate 42 by using liquid phase epitaxy.

As shown in FIGS. 7 and 9, the bicrystal substrate 42 comprises six crystal phases 42a, 42b, 42c, 42d, 42e, and 42f, which are coupled together at junction interfaces 43a, 43b, 43c, 43d, and 43e. The six crystal phases 42a to 42f are comprised of the same material as the crystal phases 22a and 22b already described above.

In the bicrystal substrate 42, adjacent crystal phases of the six crystal phases 42a to 42f are coupled at the same angle, so that the angle θ₁ between the axis of the (100) face of the each crystal and the junction interface 43 is the same for each crystal phase. For example, this angle may be 22.5 degrees. The axes of the (100) faces of adjacent crystal phases of the six crystal phases 42a to 42f are thus coupled symmetrically with the junction interface 43 as a reference. Therefore, this type of bicrystal substrate 42 will be termed a “symmetrical base” as in the earlier explanation.

The oxide superconducting film 45 is provided on approximately the entire face of the bicrystal substrate 42, and is provided in the teeth of comb-like shape near the junction interfaces 43a to 43e.

As shown in FIGS. 7 and 8, the oxide superconducting film 45 comprises terminal films 45a and 45b, and a great number of junction film sections 45c, which join the terminal films 45a and 45b with crossing the junction interfaces 43a to 43e.

Furthermore, the terminal film 45a comprises electrode films 45d, 45e, and 45f, which are provided on the crystal phases 42a, 42c, and 42e respectively, and join films 45g and 45h, which are provided on the crystal phases 42b and 42d and join the electrode films 45d, 45e, and 45f respectively.

Furthermore, the terminal film 45b comprises electrode films 45i, 45j, and 45k, which are provided on the crystal phases 42b, 42d, and 42f respectively, and join films 45m and 45n, which are provided on the crystal phases 42c and 42e and join the electrode films 45i, 45j, and 45k respectively.

The electrode films 45d to 45f and 45i to 45k are separated by the junction film sections 45c, and are arranged so as to mesh together.

The junction film sections 45c are provided between the electrode films 45d to 45f and 45i to 45k respectively, and are arranged along the junction interfaces 43a to 43e.

Since the oxide superconducting film 45 is grown by liquid phase epitaxy, its crystal structure reflects that of the crystal phases 42a to 42f of the substrate.

Therefore, the crystal axis direction of the junction film sections 45c is different on either side of the junction interfaces 43a to 43e, the angle between the crystal axis of the junction films sections 45c on the terminal film 45a side and the junction interfaces 43a to 43e being symmetrical with the angle between the crystal axis of the junction films sections 45c on the terminal film 45b side and the junction interfaces 43a to 43e, with the junction interfaces 43a to 43e as the reference.

Consequently, two or more Josephson junctions 41 are formed on the junction interfaces 43a to 43e.

In the present invention, the Josephson junctions 41, which are formed on the junction interfaces 43a to 43e of the symmetrical base as described above, will be termed symmetrical Josephson junctions, as in the case of the Josephson junction 31.

Since the magnetic field dependency of the critical current of the above symmetrical Josephson junction 41 is the same as that shown in FIG. 2, the magnetic field from the coil 18 can be used to switch the superconducting switch element 1 from the superconductive state to the normal-conductive state, and vice versa.

The width and thickness of the Josephson junctions 41 match the width and film-thickness of the junction film sections 45c. More specifically, the width and thickness are the same as the Josephson junction 31 described above.

For sake of convenience, FIG. 7 shows only sixty-nine Josephson junctions 41 (junction film sections 45c) in the superconducting switch element 1b, but in reality, several thousand to several ten-thousand Josephson junctions 41 are provided.

Since the superconducting switch element 1b comprises the multiple Josephson junctions 41 connected in parallel, the critical current of the entire element is the integral of the critical current of the Josephson junctions 41 and the number of Josephson junctions 41 per element. Therefore, in order to increase the current to the superconducting switch element 1b, the number of Josephson junctions 41 per element need only be increased.

The number of Josephson junctions 41 which are provided for the single superconducting switch element 1b may be increased by using a multilayered structure, obtained by laminating multiple oxide superconducting films 45 on the bicrystal substrate 42, and providing a Josephson junction in each oxide superconducting film.

According to the superconducting switch element 1b shown in FIG. 7, two or more junction interfaces 45a to 45f are provided on one bicrystal substrate 42, and a great number of Josephson junctions 41 are provided on the junction interfaces 45a to 45f. Therefore, the critical current of the superconducting switch element itself can be increased, and a larger current can be fed through.

The bicrystal oxide superconducting films 25 and 45 comprise ReBa₂Cu₃O_{7-δ} (where Re is at least one type of rare earth element and Y), but there are no particular restrictions on the composition of these films.

Since the bicrystal oxide superconducting films 25 and 45 are provided on the bicrystal substrates 22 and 42, two crystal phases are coupled at the Josephson junctions 31 and 41. As shown, for example, in FIG. 6, the angle (θ2) between the junction face of the Josephson junctions 31 and the crystal axis (a axis) of the crystal grains in the two crystal phases (i.e. the junction angle) reflects precisely the junction angle (θ1) between the junction interface 23 of the substrate 22 and the two crystal phases 22a and 22b. The two crystal grains which form the junction interface (Josephson junction 31) of the bicrystal oxide superconducting film 25 are both in the c axis direction, and the grain interface of these two crystal grains comprises a {130} face and a {130} face, or a {120} face and a {120} face.

When the grain interface of the two crystal grains which form Josephson junctions 31 and 41 of the bicrystal oxide superconducting films 25 and 45 is comprised of the above-mentioned faces, the angle θ₂ between the crystal axis (a axis) direction of both crystals and the junction interface is a symmetrical angle of 22.5 degrees.

Since the bicrystal oxide superconducting films 25 and 45 are provided on the bicrystal substrates 22 and 42 by liquid phase epitaxial growth in a state resembling thermal equilibrium, they can be made zero-point several μm or thicker. Furthermore, by controlling manufacturing conditions, the join interface can be made a straight line of several μm or longer.

A seed crystal should preferably be provided between the bicrystal substrates 22 and 42 and the bicrystal oxide superconducting films 25 and 45.

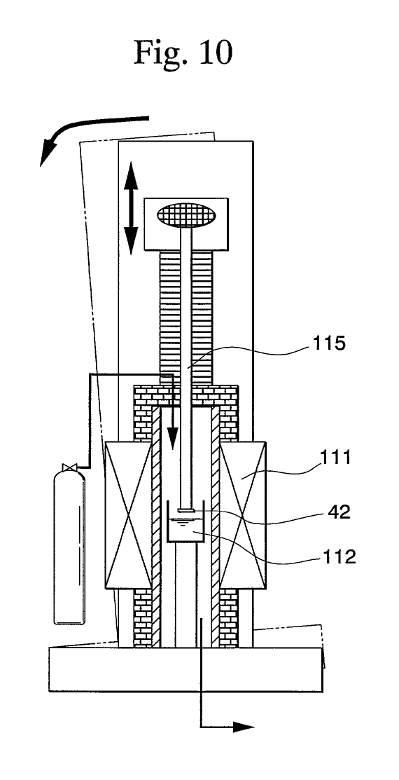

Subsequently, one example of a method for manufacturing the bicrystal oxide superconducting film will be explained in detail, taking an as example the superconducting switch element 1b shown in FIGS. 7 to 9, and based on the liquid phase epitaxial growth apparatus shown in FIG. 10.

The liquid phase epitaxial growth apparatus shown in FIG. 10 has the same structure as a liquid crystal apparatus, such as a liquid crystal apparatus employing the Czochralski method which is used in manufacturing single-crystals. In this apparatus, raw elements which form a fused liquid for making an ReBa₂Cu₃O_{7-δ} oxide superconducting body (where Re is at least one type of rare earth element selected from Y, Nd, Sm, and the like), e.g. an oxide superconducting body comprising Y—Ba—Cu—O, are provided in a furnace 111 such as an electric furnace; a bicrystal substrate 42, comprising MgO and the like and having a thin film of seed crystal on its surface, is provided directly thereabove. The bicrystal substrate 42 is coupled to the bottom end of a rotating axis 115.

The apparatus manufactures the bicrystal oxide superconducting film 45 by fusing the raw elements by heating them in the furnace 111 to form a fused liquid 112, immersing the substrate 42 on the surface of the fused liquid 112, the substrate 42 being rotated and slowly raised by the rotation of the rotating axis 115, and growing crystal on the substrate 42. As a result, the bicrystal oxide superconducting film 45 provided on the substrate 42 has a coupling interface at the same position as the substrate 42, and the same junction gradient as the substrate (i.e. the angle of the crystal axes of both crystals is an symmetrical angle of 45 degrees). In this example, a clean and smooth surface is obtained by slightly tilting the apparatus (by several degrees) during liquid phase growth.

The materials mentioned above are used as the substrate 42.

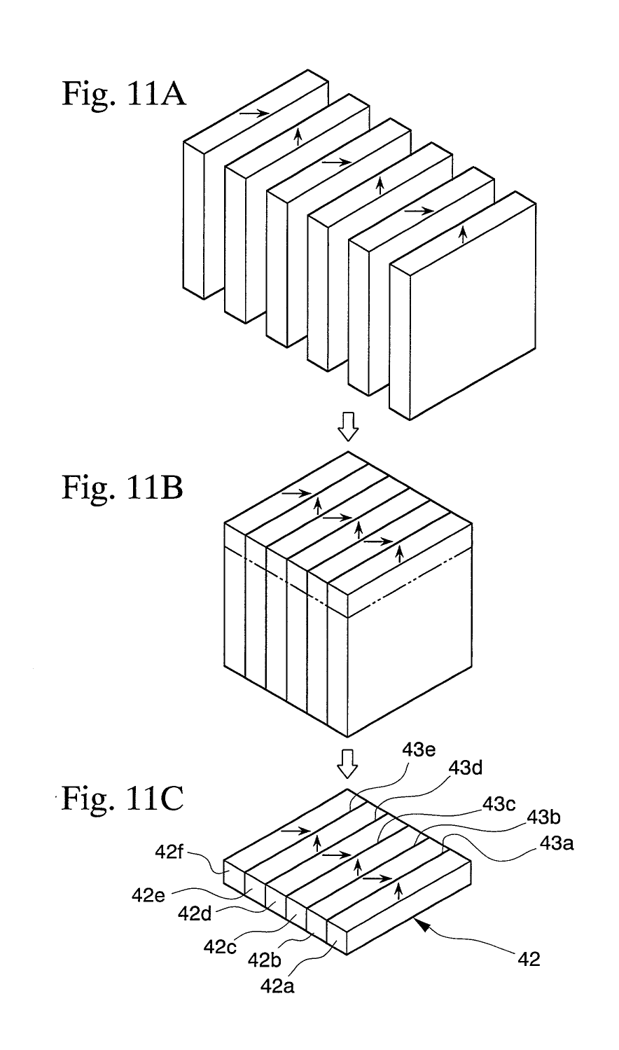

As shown for example in FIGS, 11A to 11C, the bicrystal substrate 42 comprising the crystal phases 42a to 42f is made by pasting six single crystal substrates together (FIG. 11A), sintering the single crystal substrates into a single body (FIG. 11B), cutting along the dashed line of FIG. 11B, and polishing and smoothing the cutoff surface (FIG. 11C).

It is not essential that a seed crystal be provided to the substrate 42, since this depends on the material of the substrate and the bicrystal, but it is preferable to provide one. The thickness of the seed crystal should be approximately 10 to 500 nm, i.e. a seed film. The seed film can be provided by using pulse laser deposition (PLD), metal organic chemical vapor deposition (MOCVD), sputtering, or thermal plasma deposition, but the PLD and sputtering methods are to be preferred for reasons of simplicity. The seed crystal need not be a complete superconducting crystal, an incomplete one is acceptable. An NdGaO₃ substrate is one example of one in which it is not essential to provide a seed crystal.

In the bicrystal oxide superconducting film 45 which is provided on the bicrystal substrate 42, the positions of the Josephson junctions 41 and the angle θ₂ formed by the crystal axes (a axis) of the two crystal grains which form the Josephson junction (i.e. the junction angle) precisely reflect the position of the junction interfaces 43a to 43f and the junction angle θ1 of the bicrystal substrate 42.

In the present invention, there are no particular restrictions on the material used in manufacturing the bicrystal oxide superconducting film 45, which may comprise any material which permits a superconductor to be manufactured by using fused liquid. In addition to YBCO superconductors, there are also NdBaCuO, SmBaCuO superconductors, and the like, any of which can be expressed as ReBa₂Cu₃O_{7-δ} (where Re is at least one type of rare earth element selected from Y, Nd, Sm, and the like). Furthermore, the thickness of the manufactured film should be between 0.1 to 100 μm, although the preferable thickness differs in accordance with the intended purpose, i.e. the purpose of the electrical element, such as a Josephson junction element and a SQUID, which is to be made by using the film.

The length of the junction interface (the Josephson junction 41) formed by the two crystals of the bicrystal oxide superconducting film 45 when arranged in a straight line should be 0.5 μm or more, much longer than the length of 10 to 100 nm when using the conventional method of gaseous phase growth, and preferably 1.0 μm. The present invention uses liquid phase growth, enabling the length of the junction interface to be 100 μm or more.

The liquid phase growth method, which can be used in manufacturing the bicrystal oxide superconducting film of the present invention, is not limited to the liquid phase epitaxy method used in the liquid phase growth apparatus specified in FIG. 10, and it is acceptable to use any method which enables a thin-film or thick-film to be made by liquid growth, such as, for example, simple solidifying method and the like. The furnace for heating in the liquid phase growth apparatus shown in FIG. 10 is not limited to a resistance heating furnace, and may comprise a high-frequency heating furnace or the like, it being necessary only that the furnace can smoothly fuse the raw elements for making the superconductor. There are no particular restrictions on the atmosphere in the furnace, which may comprise air, a vacuum, nitrogen atmosphere, oxygen atmosphere, or the like.

To manufacture the superconducting switch element 1b of the present invention, the junction film sections 45c are provided by, for example, etching a predetermined line width by photolithography and etching using a convergent ion beam in one part of the bicrystal oxide superconducting film 45, formed on the entire face of the substrate 42. The junction film sections 45c are provided so that the position of the Josephson junction 41 of the bicrystal oxide superconducting film 45 intersects (i.e. cuts across) the long direction of the junction film sections 45c.

According to the superconducting power circuit A described above, the superconducting switch elements 1 to 4 having two or more Josephson junctions are inserted in each side of the bridge circuit 5, and, since the superconducting switch elements 1 to 4 have large critical current, a large, low-voltage ac current can be supplied to the bridge circuit 5, and a large, low-voltage dc current for driving the outside circuit 14 comprising a superconductor can be easily obtained.

Furthermore, since the current to the superconducting power circuit A is high but has a low voltage, a low-resistant capacitor 13 can be used as the low frequency smoothing filter. Consequently, the dielectric thickness of the capacitor itself can be made thin, increasing the electrostatic capacity, and the pulsating current (all wave rectified current), which is output from the bridge circuit 5, can be smoothed to dc current.

Furthermore, since the switching speed of the superconducting switch elements 1 to 4 is rapid, a high-frequency current can be supplied, increasing the effect of the capacitor and improving smoothing, thereby obtaining a more stable dc current.

Furthermore, although the resistance of the Josephson junctions 31 and 41 is approximately several ohms in the normal-conductive state, since the Josephson junctions 31 and 41 are connected in parallel, the resistances of the superconducting switch elements 1 to 4 become approximately 10⁻³ to 10⁻⁵ Ω, achieving superior switching characteristics.

Embodiment 2

A superconducting power circuit according to a second embodiment of the present invention will be explained with reference to the drawings.

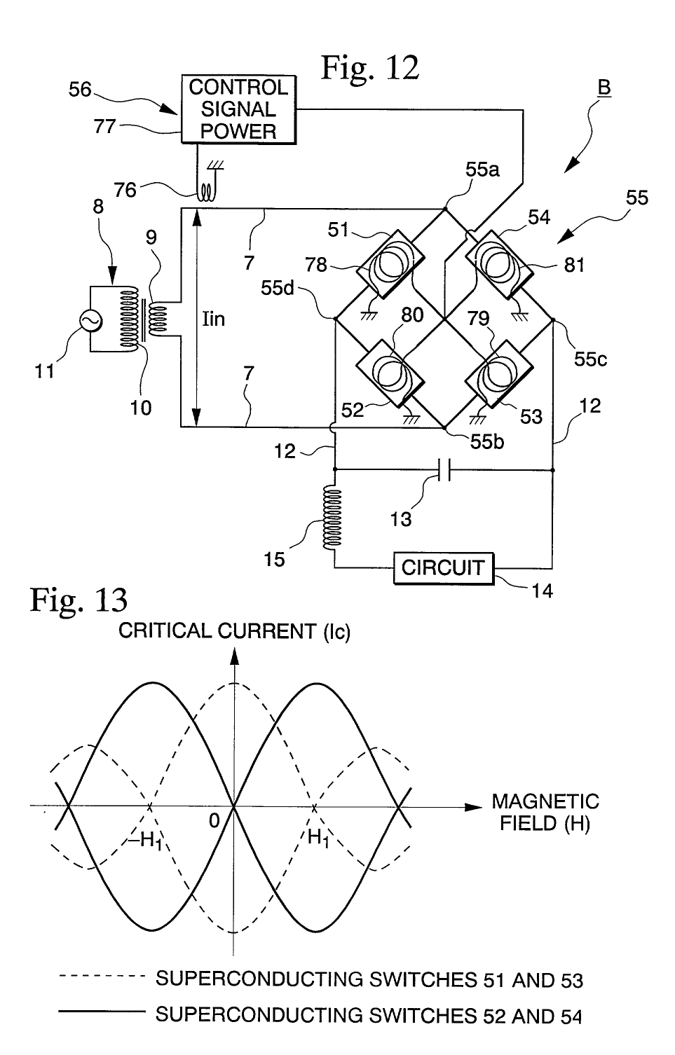

Constituent elements of the superconducting power circuit B shown in FIG. 12 which are identical to those of the superconducting power circuit A shown in FIG. 1 are represented by identical reference symbols, and will not be explained furthermore.

The superconducting power circuit B shown in FIG. 12 converts ac current to dc current, and mainly comprises (i) a bridge circuit 55, comprised by arranging four superconducting switch elements 51, 52, 53, and 54 on sides of a bridge line, and (ii) a controller 56 which switches the superconducting switch elements 51 to 54.

A transformer 8 is connected via input lines 7 to terminals 55a and 55b on the input side of the bridge circuit 55.

Furthermore, a capacitor 13, a circuit 14, and a coil (inductance) 15 are connected via output lines 12 to terminals 55c and 55d on the output side of the bridge circuit 55.

The superconducting switch elements 51 to 54 have two or more Josephson junctions which can be freely switched to/from normal conductivity and superconductivity by an outside magnetic field.

The Josephson junctions of the superconducting switch elements 51 and 53 comprise what are termed s-s wave junctions. That is, as shown by the broken lines in FIG. 13, the magnetic field dependency of the critical current of the elements comprising such a Josephson junction is characterized in that the critical current I, reaches its maximum when the magnetic field H is zero, and becomes zero when the magnetic field H is ±H₁.

The Josephson junctions of the superconducting switch elements 52 and 54 are different from the s-s wave junctions. As shown by the sold lines in FIG. 13, the magnetic field dependency of the critical current of the elements 52 and 54 comprising the Josephson junctions is characterized in that the critical current I_{c} is zero when the magnetic field H is zero, and reaches its maximum when the magnetic field H is ±H₁.

Therefore, the superconducting switch elements 51 and 53 become superconductive when the outside magnetic field is zero, and become normal-conductive when the outside magnetic field has been applied. On the other hand, the superconducting switch elements 52 and 54 become normal-conductive when the outside magnetic field is zero, and become superconductive when the outside magnetic field has been applied.

As shown in FIG. 12, the controller 56 comprises a polarity detector 76, comprising a coil and the like provided adjacent to the input lines 7, a control signal source 77 which generates a rectangular control current based on the result detected by the polarity detector 76, and coils 78 to 81 which function as a magnetic field generating section, provided adjacent to the superconducting switch elements 51 to 54. The coils 78 to 81 split from the control signal source 77 and are provided near the superconducting switches 51 to 54 respectively.

In the polarity detector 76, the input ac current Iᵢₙ induces a detected current, which is input to the control signal source 77. The control signal source 77 amplifies the detected current, and supplies a rectangular-wave control current to the coils 78 to 81.

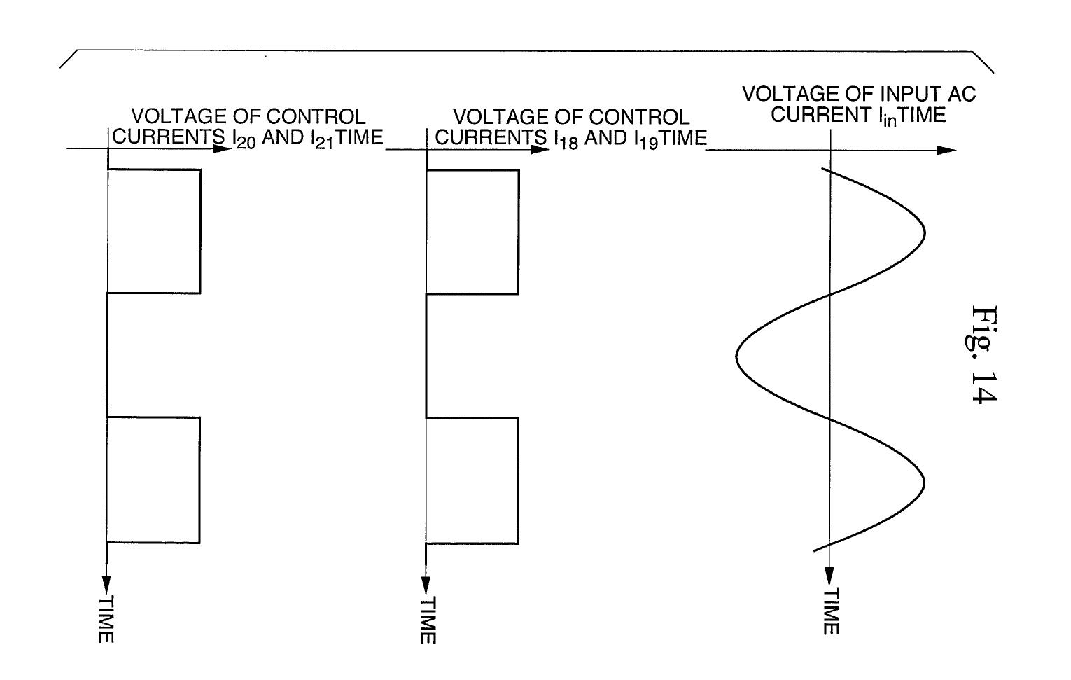

FIG. 14 shows waveforms of the input ac current Iᵢₙ which is input to the bridge circuit 55, the control currents I₇₈ and I₇₉ which are applied to the coils 78 and 79, and the control currents I₈₀ and I₈₁ which are applied to the coils 80 and 81.

Each of the control currents which are made rectangular by the control signal source 77 has the same phase as the input ac current Iᵢₙ. As shown in FIG. 14, the control currents I₇₈, I₇₉, I₈₀, and I₈₁, which are applied to the coils 78 to 81, are the same phase as the input ac current Iᵢₙ.

Subsequently, the operation of the superconducting power circuit B will be explained.

When an outside magnetic field is applied to the superconducting switch elements 51 and 53, the elements 51 and 53 switch from the superconductive state to the normal-conductive state. When an outside magnetic field is applied to the superconducting switch elements 52 and 54, the elements 52 and 54 switch from the normal-conductive state to the superconductive state.

Therefore, when the voltage of the input ac current Iᵢₙ is positive, the control currents I₇₈ to I₈₁ apply an outside magnetic field to the superconducting switch elements 51 to 54, whereby one pair of the superconducting switch elements 51 and 53 become normal-conductive and the other pair of the superconducting switch elements 52 and 54 become superconductive.

The superconducting switch elements 52 and 54 have zero electrical resistance in the superconductive state, and the superconducting switch elements 51 and 53 have finite electrical resistance in the normal-conductive state. Therefore, the current in the superconducting power circuit B flows through the superconducting switch elements 52 and 54 but not through the superconducting switch elements 51 and 53.

Therefore, when the voltage of the input ac current Iᵢₙ is positive, the current in the superconducting power circuit B flows from the terminal 55a via the superconducting switch element 54 to the terminal 55c, via the circuit 14, and from the terminal 55d via the superconducting switch element 52 to the terminal 55b.

As time elapses and the voltage of the input ac current Iᵢₙ has become negative, in converse to the case described above, the superconducting switch elements 52 and 54 switch from the superconductive state to the normal-conductive state and have finite resistances, whereas the superconducting switch elements 51 and 53 switch from the normal-conductive state to the superconductive state and zero resistance.

As a result, the current in the superconducting power circuit B flows through the superconducting switch elements 51 and 53 but not through the superconducting switch elements 52 and 54; therefore, the current in the superconducting power circuit B in this case flows from the terminal 55b via the superconducting switch element 53 to the terminal 55c, via the circuit 14, and then from the terminal 55d via the superconducting switch element 51 to the terminal 55a.

As a result, even when the polarity of the input ac current Iᵢₙ has changed, current on the output side of the bridge circuit 55 always flows from the terminal 55c via the circuit 14 to the terminal 55d. That is, dc current flows to the circuit 14.

By using the controller 56 to switch one pair of the superconducting switch elements to the superconductive state, and switch the other pair to the normal-conductive state in this way, ac current can be converted to dc current.

Subsequently, the constitution of the superconducting switch elements 51 to 54 will be explained.

Of these four superconducting switch elements, the pair of superconducting switch elements 51 and 53, provided on the diagonal line of the bridge circuit 55, have Josephson junctions wherein the critical current exhibits polarity when the magnetic field is zero; the superconducting switch elements 51 and 53 have the same constitution as the superconducting switch elements 1 to 4 which were described in the first embodiment. This constitution was shown in FIGS. 4, 5, and 7 to 9 and will not be explained further.

The other pair of superconducting switch elements 52 and 54 have Josephson junction wherein the critical current exhibits is zero at zero magnetic field. The superconducting switch elements 52 and 54 differ from the superconducting switch elements 51 and 53 in respect of the crystal structures of their bicrystal substrates.

On the other hand, the pattern of the oxide superconducting film which is provided on the bicrystal substrate is the same as that shown in FIGS. 4, 5, and 7 to 9, and for this reason will not be explained in further detail.

The bicrystal substrates of the superconducting switch elements 52 and 53 comprise two crystal phases which are joined at a junction interface, and in this respect are the same as those of the superconducting switch elements 1 to 4 described above.

In the above bicrystal substrates, two crystal phases are joined so that the angles between the axes of the (100) faces of the crystals and the junction interface are different. That is, the (100) face axes of the two crystal phases become asymmetrical with the junction interface as a reference; this type of bicrystal substrate 92 is termed an “asymmetrical substrate” in the present invention.

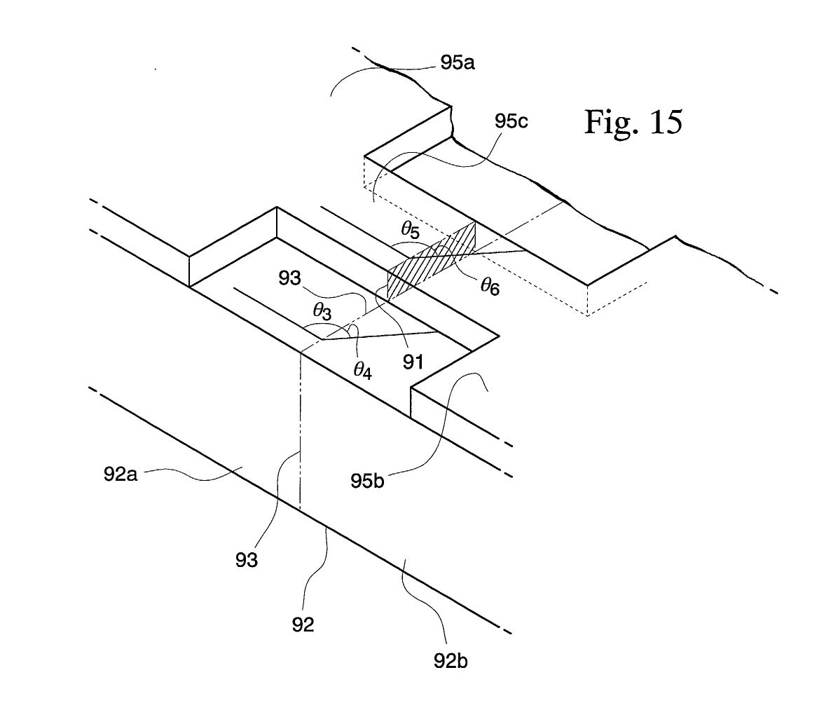

FIG. 15 shows the detailed constitution of a Josephson junction provided on an asymmetrical base and an asymmetrical substrate thereof.

The bicrystal substrate 92 is an asymmetrical substrate. The crystal phases 92a and 92b of the bicrystal substrate 92 are joined together at a junction interface 93. In FIG. 15, the angle θ₃ between the axis of the (100) face of the crystal grain forming the crystal phase 92a and the junction interface 93 is 90 degrees, and the angle θ₄ between the axis of the (100) face of the crystal grain forming the crystal phase 92b and the junction interface 93 is 45 degrees.

Therefore, (110) is exposed at the junction interface of the crystal phase 92a, and (010) is exposed at the junction interface of the crystal phase 92b.

The oxide superconducting film 95 is grown by liquid phase epitaxy on the bicrystal substrate 92; for this reason, near the junction interface 93 of the bicrystal substrate 92, the oxide superconducting film 95 reflects the crystal structure of the crystal phases 92a and 92b of the substrate. That is, the direction of the crystal axis of the oxide superconducting film 95 is different on either side of the junction interface 93 of the bicrystal substrate 92.

The crystal axis direction of the oxide superconducting film 95 is different on each side of the junction interface 93, the gradient angle θ₅ between the crystal axis direction and the junction interface (Josephson junction) on one side being 90 degrees, and the gradient angle θ₆ between the crystal axis direction and the junction interface (Josephson junction) on the other side being 45 degrees; angles θ₅ and θ₆ are consequently asymmetrical with the junction interface 93 as a reference.

Therefore, a Josephson junction 91 is formed on the junction interface 93. In FIG. 15, the Josephson junction 91 is represented by a diagonally-shaded section. In the present invention, the Josephson junction 91, which is provided on the junction interface of an asymmetrical substrate as mentioned above, is termed an asymmetrical Josephson junction.

The magnetic field dependency of the critical current of the asymmetrical Josephson junction 91 is the same as that shown by the solid line in FIG. 13, the critical current I_{c} becoming zero when the magnetic field H is zero, and reaching its maximum when the magnetic field H is ±H₁. Therefore, the magnetic field from the coils 80 and 81 can be used to switch the superconducting switch elements 52 and 54 from the superconductive state to the normal-conductive state, and vice versa.

The width and thickness of the Josephson junction 91 are the same as those of the Josephson junctions 31 and 41, and should preferably be slightly larger than the magnetic field penetration depth of the Josephson junction 91. For instance, when the magnetic field penetration depth is 2 μm, the width and thickness of the Josephson junction 91 should each be approximately 5 μm.

The superconducting switch elements 51 to 54 comprise a plurality of junction-type and non-junction-type Josephson junctions, connected in parallel. Therefore, the critical current of an entire element is the integral of the critical current value of a Josephson junction and the number of Josephson junctions per element. In order to increase the current to the superconducting switch elements 51 to 54, the number of Josephson junctions per element need only be increased.

According to the superconducting power circuit B described above, in addition to similar effects of the superconducting power circuit A of the first embodiment, the following effects can be obtained.

In the superconducting power circuit B, the bridge circuit 55 comprises the superconducting switch elements 51 to 54 having symmetrical Josephson junctions and asymmetrical Josephson junctions, and coils, excited by same-phase control current, are provided near the superconducting switch elements, thereby enabling ac current to be converted to dc current, and simplifying the circuit constitution of the controller 56 since it is not necessary to adjust the phase of the control current for each of the individual superconducting switch elements.

### Examples

### Example 1

Using the liquid phase growth apparatus shown in FIG. 10, an oxide superconducting film was grown in a c-axis arrangement on a bicrystal substrate, obtaining a bicrystal oxide superconducting film. Slightly tilting the entire apparatus during this process, as described above, achieves a clean film surface with no heterogeneous phase; in this example the apparatus was tilted to an angle of 3 degrees. An MgO bicrystal substrate having two crystal phases was used as the substrate.

The substrate is symmetrical, the angle between the (100) axis of each crystal phase and the junction interface being 24 degrees.

In making the bicrystal oxide superconducting film, a seed film of YBaCuO is provided in advance on the bicrystal substrate. The seed film was provided by using pulse laser deposition in 100 mTorr under oxygen atmosphere at a substrate temperature of 680 to 730° C. The frequency of the laser was 5 Hz.

Y₁Ba₂Cu₃Oₓ powder and Ba₃Cu₇O₁₀ powder were homogeneously mixed at a mass ratio of 10:90, and the mixed powder was used as the raw component for making the oxide superconducting film, being melted by heating in a furnace at a temperature of 960 to 970° C. After melting, the temperature of the molten fluid was increased to 980 to 1050° C. and held at this temperature for one hour. At excess saturation after cooling to 910 to 970° C., the substrate having the seed film provided thereon was made to slightly contact the molten surface, and was rotated in that position for approximately one minute.

The substrate was slowly pulled away while continuing the rotation, thereby growing a bicrystal oxide superconducting film on the entire surface of the substrate. The film grew under nitrogen atmosphere, the rotation speed of the substrate was 80 rpm, and the pull-away speed of the substrate was 2 μm per minute. The thickness of the film was 5 μm.

A resist film was provided on the oxide superconducting film, provided on the entire surface of the substrate, the resist was exposed by a mask of a predetermined pattern, and a photolithography technique such as etching was used to manufacture the superconducting switch element shown in FIGS. 4 and 5.

One-thousand Josephson junctions, each having a width of 5 μm and a thickness of 5 μm, were provided in the obtained element. The bicrystal substrate was made substantially square when viewed in the flat position, one side of the square being 10 mm.

The superconducting switch element was placed in 77 K of liquid nitrogen, and its various characteristics were measured. The critical current value per Josephson junction was 3 mA, and the critical current value of the entire superconducting switch element was 3 A.

Furthermore, the critical current density per one Josephson junction was 10⁴A/cm².

By laminating Josephson junctions having a thickness of 5 μm, the critical current of the superconducting switch element comprising 33,000 Josephson junctions becomes 100 A.

In the superconducting switch element described above, a great number of Josephson junctions are connected in parallel in this way, enabling a current of approximately 100 A to be passed therethrough.

### Example 2

The superconducting switch element shown in FIGS. 7 to 9 was made in the same manner as in the first embodiment, the only differences being that the bicrystal substrate comprised six crystal phases joined together and a different mask pattern was used in the process of photolithography. The bicrystal substrate was made substantially square when viewed in the flat position, one side of the square being 10 mm, and the angle between the axis of each crystal phase and the junction interface was 24 degrees.

Three-thousand Josephson junctions having a width of 5 μm and a thickness of 5 μm were provided along five junction interfaces of the superconducting switch element.

When the characteristics of the superconducting switch element were measured by the same method as in the first embodiment, the critical current of the entire superconducting switch element was 10 A, which is approximately three times or more that of the superconducting switch element in the first embodiment.

By using the superconducting switch element, a power circuit comprising superconductors having a scale of 10⁵ Josephson junctions (JJ) can be achieved.

The technological field of the present invention is not limited to the embodiments described above, and may be additionally modified in various ways without deviating from the main features of the present invention.

For example, a superconducting switch element comprising asymmetrical Josephson junctions may be used in the superconducting power circuit A of the first embodiment.

Furthermore, instead of an ac power supply, a dc power supply may be connected to the input sides of the bridge circuits 5 and 55 of the superconducting power circuits A and B of the first and second embodiments. The dc current can be converted to ac current by driving the controller at a predetermined ac frequency.

Moreover, instead of a Josephson junction, a superconducting quantum interference device (SQUID) comprising a superconducting ring of two or more Josephson junctions may be used as the superconducting switch element.

What is claimed is:

1. A superconducting power circuit comprising:
a bridge circuit comprising superconducting switch elements having two or more Josephson junctions incorporated at each side of a bridge line; and
a control section which uses an outside magnetic field to switch a pair of said superconducting switch elements, arranged on opposite sides of said bridge circuit, to a superconductive state, and switch another pair of said superconducting switch elements to a normal-conductive state.

2. The superconducting power circuit according to claim 1, wherein, when the voltage of an ac current applied to said bridge circuit is positive, said control section switches said pair of said superconducting switch elements to the superconductive state, and switches said other pair of said superconducting switch elements to the normal-conductive state; and
when the voltage of an ac current applied to said bridge circuit is negative, said control section switches said pair of said superconducting switch elements to the normal-conductive state, and switches said other pair of said superconducting switch elements to the superconductive state.

3. The superconducting power circuit according to claim 1, said control section comprising a polarity detecting section which detects the polarity of said ac current, a control signal power supply which generates a control current based on the detection result of said polarity detecting section, and a magnetic field generating section, which is provided adjacent to said superconducting switch elements and switches said superconducting switch elements by converting said control current to said outside magnetic field.

4. The superconducting power circuit according to claim 1, wherein a transformer comprising at least a secondary winding provided in a superconducting line is connected to the input side of said bridge circuit.

5. The superconducting power circuit according to claim 1, wherein a dc power supply is connected to the input side of said bridge circuit.

6. The superconducting power circuit according to claim 1, said superconducting switch elements comprising two or more Josephson junction elements or two or more superconducting quantum interference devices, comprising two or more Josephson junctions, connected in parallel.

7. The superconducting power circuit according to claim 6, said Josephson junction comprising a bicrystal superconducting film which is grown by liquid phase epitaxy on a bicrystal substrate, comprising at least two or more crystal phases which are joined at a junction interface.

8. The superconducting power circuit according to claim 7, wherein, when a symmetrical bicrystal substrate is one in which the angles between axes of adjacent crystal phases and said junction interface are symmetrical with said crystal grain interface as a reference, said four superconducting switch elements comprise Josephson junctions which are comprised of bicrystal superconducting film provided on said symmetrical substrate.

9. The superconducting power circuit according to claim 7, wherein, when an asymmetrical bicrystal substrate is one in which the angles between axes of adjacent crystal phases and said junction interface are asymmetrical with said crystal grain interface as a reference, said four superconducting switch elements comprise Josephson junctions which are comprised of bicrystal superconducting film provided on said asymmetrical substrate.

10. The superconducting power circuit according to claim 7, wherein, when a symmetrical bicrystal substrate is one in which the angles between axes of adjacent crystal phases and said junction interface are symmetrical with said crystal grain interface as a reference, and an asymmetrical bicrystal substrate is one in which the angles between axes of adjacent crystal phases and said junction interface are asymmetrical with said crystal grain interface as a reference, said pair of superconducting switch elements comprise Josephson junctions which are comprised of bicrystal superconducting film provided on said symmetrical substrate, and said other pair of superconducting switch elements comprise Josephson junctions which are comprised of bicrystal superconducting film provided on said asymmetrical substrate.
